(19) United States
(12) Patent Application Publication
(10) Pub. No.: US 2015/0019147 A1
(43) Pub. Date: Jan. 15, 2015

(54) METHOD AND DEVICE FOR ESTIMATING DAMAGE TO MAGNETIC TUNNEL JUNCTION (MTJ) ELEMENTS

(71) Applicant: QUALCOMM Incorporated, San Diego, CA (US)

(72) Inventors: Xia Li, San Diego, CA (US); Xiaochun Zhu, San Diego, CA (US); Seung H. Kang, San Diego, CA (US)

(21) Appl. No.: 13/939,243

(22) Filed: Jul. 11, 2013

(51) Int. Cl. G01R 31/26

(52) U.S. Cl. CPC G01R 31/26
USPC 702/58

(57) ABSTRACT

For first and second magnetic tunnel junction (MTJ) elements, a trend in a relationship between an electrical characteristic of the first and second MTJ elements and an area of the first and second MTJ elements may be determined. Damage to a sidewall of the first and second MTJ elements may be estimated from the trend. At least one operating parameter of an MTJ manufacturing apparatus may be modified based on an X or Y intercept a trend line.

### FIELD OF THE DISCLOSURE

The present application for patent is directed toward estimating damage to the magnetic barrier layer and/or the free layer of magnetic tunnel junction (MTJ) elements and toward a method of optimizing a device based on the estimate, and, more specifically, toward estimating damage to the magnetic barrier layer and/or a free layer of MTJ elements based on a trend in a relationship between an electrical characteristic of the MTJ elements and an area of the MTJ elements and toward a method of optimizing a device based on the estimate.

### BACKGROUND

Magnetic tunnel junction (MTJ) elements comprise first and second magnetic elements separated by a layer of magnetic barrier material. The magnetic orientation of the first magnetic element is fixed, and the magnetic orientation of the second magnetic element can be changed by applying a magnetic field or a current to the MTJ element, depending on the type of MTJ used. The MTJ element has a first resistance when the magnetic orientations of the first and second magnetic elements are the same or parallel and a second, different, resistance when the magnetic orientations of the first and second magnetic elements are opposite or antiparallel. These two states can be used to represent a digital “0” and “1,” and an MTJ element can thus be used as a memory element in which the measured resistance indicates the magnetic orientation of the second magnetic element and thus the binary value stored by the MTJ element.

During the manufacture and/or processing of MTJ elements, the sidewalls of the MTJ elements may be chemically or physically damaged. For example, when processing is carried out using certain etchants and encapsulants, oxygen and/or other elements can diffuse into the periphery of the magnetic barrier layer and the free layer and chemically damage the layers. Other processing steps can physically damage the magnetic bather layer and the free layer. This damage comprises a ring-shaped outer region of the magnetic barrier layer that has a higher or lower resistance than that of the undamaged material in the center of the magnetic barrier layer. This damage affects the resistance of the MTJ elements and reduces their effective working areas. Such damage may make it more difficult to determine whether a given measurement of the MTJ elements indicates that they are in parallel or antiparallel states. This problem becomes more pronounced as the size of the MTJ elements decreases. It would therefore be desirable to estimate the amount and/or type of damage to MTJ elements so that manufacturing processes can be tuned to minimize and/or better control this damage.

### SUMMARY

A first aspect of the disclosure comprises a method that includes providing first and second magnetic tunnel junction (MTJ) elements, determining a trend in a relationship between an electrical characteristic of the first and second MTJ elements and an area of the first and second MTJ elements, and estimating damage to a sidewall of the first and second MTJ elements from the trend if we assume MTJ sidewall damage is same for different MTJ size elements.

Another aspect of the disclosure comprises a method that includes providing an apparatus for producing MTJ elements having at least one settable process parameter, and setting the at least one settable process parameter to a present setting. The method also includes producing first and second MTJ elements using the apparatus with the at least one settable process parameter set to the present setting, and determining a trend in a relationship between a switching current of the first and second MTJ elements and an area of the first and second MTJ elements. The method also includes determining from the trend whether the switching current approaches a positive or negative value as the area of the MTJ element approaches zero, and, if the switching current approaches a positive value or a negative value as the area of the MTJ element approaches zero, changing the present setting of the at least one settable process parameter to a new setting.

A further aspect of the disclosure comprises a method that includes steps for providing first and second MTJ elements, steps for determining a trend in a relationship between an electrical characteristic of the first and second MTJ elements and an area of the first and second MTJ elements and steps for estimating damage to a sidewall of the first and second MTJ elements from the trend.

Another aspect of the disclosure comprises a method that includes providing an apparatus for producing MTJ elements having at least one settable process parameter, and steps for setting the at least one settable process parameter to a present setting. The method also includes steps for producing first and second MTJ elements using the apparatus with the at least one settable process parameter set to the present setting and steps for determining a trend in a relationship between a switching current of the first and second MTJ elements and an area of the first and second MTJ elements. In addition, the method includes steps for determining from the trend whether the switching current approaches a positive or negative value as the area of the MTJ element approaches zero and steps for, if the switching current approaches a positive value or a negative value as the area of the MTJ element approaches zero, steps for changing the at least one settable process parameter from the present setting to a new setting different than the present setting.

Another aspect of the disclosure comprises a non-transitory computer readable medium containing instructions, that, when executed by a computer cause the computer to receive information regarding the electrical characteristics of first and second MTJ elements and the areas of the first and second MTJ elements, determine a trend in a relationship between the electrical characteristics of the first and second MTJ elements and the areas of the first and second MTJ elements and output an estimate of damage to a sidewall of the first and second MTJ elements from the trend.

Another aspect of the disclosure comprises an apparatus for estimating damage to first and second MTJ elements, comprising: at least one processor configured to determine a trend in a relationship between an electrical characteristic of the first and second MTJ elements and an area of the first and second MTJ elements, and estimate damage to a sidewall of the first and second MTJ elements from the trend; and memory coupled to the at least one processor and configured to store related data and/or instructions.

Another aspect of the disclosure comprises an apparatus for estimating damage to first and second MTJ elements, comprising: means for determining a trend in a relationship between an electrical characteristic of the first and second MTJ elements and an area of the first and second MTJ elements; and means for estimating damage to a sidewall of the first and second MTJ elements from the trend.

### BRIEF DESCRIPTION OF THE DRAWINGS

The accompanying drawings are presented to aid in the description of embodiments of the invention and are provided solely for illustration of the embodiments and not limitation thereof.

FIG. 1 is a graph of a relationship between magnetic tunnel junction (MTJ) switching current and MTJ area for MTJ elements having no sidewall damage.

FIG. 2 is a graph of a relationship between MTJ switching current and MTJ area for MTJ elements having a first type of sidewall damage.

FIGS. 3A and 3B are graphs of relationships between MTJ switching current and MTJ area for MTJ elements having a second type of sidewall damage.

FIG. 4 is a schematic top plan view of an elliptical MTJ element.

FIG. 5 is a schematic top plan view of a circular MTJ element having the same area as the elliptical MTJ element of FIG. 4.

FIGS. 6A and 6B are graphs showing a relationship between the square of switching current and MTJ element diameter.

FIG. 7 is another graph relating the square root of switching current to MTJ element diameter.

FIG. 8 is a graph relating MTJ switching current to MTJ element diameter.

FIG. 9 is a flow chart illustrating a method according to an embodiment of the disclosure.

FIG. 10 is a flow chart illustrating a method according to another embodiment of the disclosure.

FIG. 11 illustrates part of the hardware that may be used to implement an apparatus for estimating damage to MTJ elements in accordance with aspects of the present disclosure.

FIG. 12 is a schematic diagram of an exemplary wireless communication system in which embodiments produced according to the disclosure may be used.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

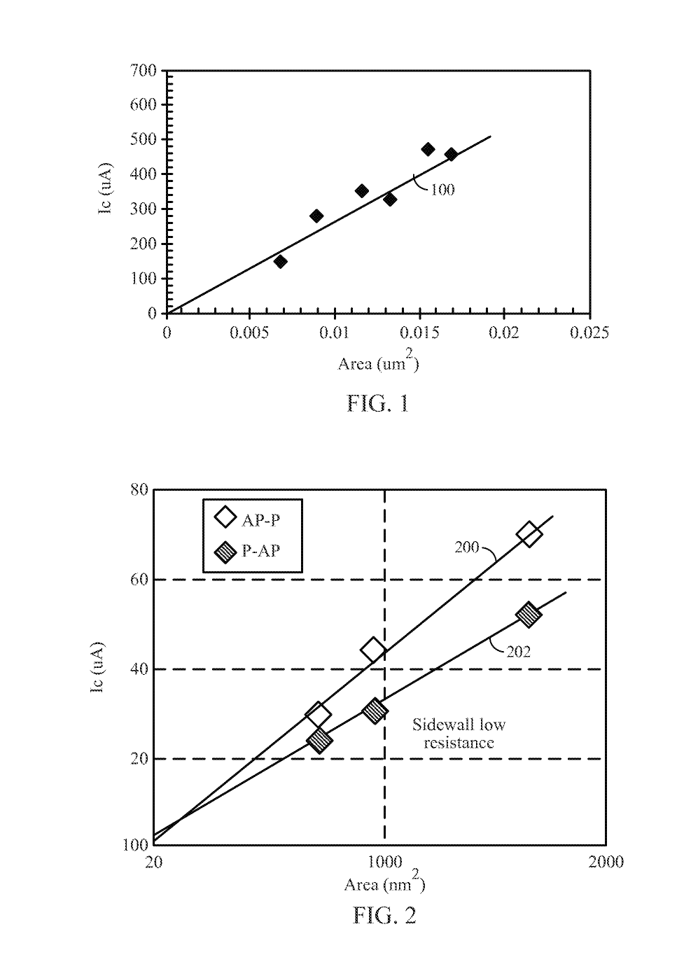

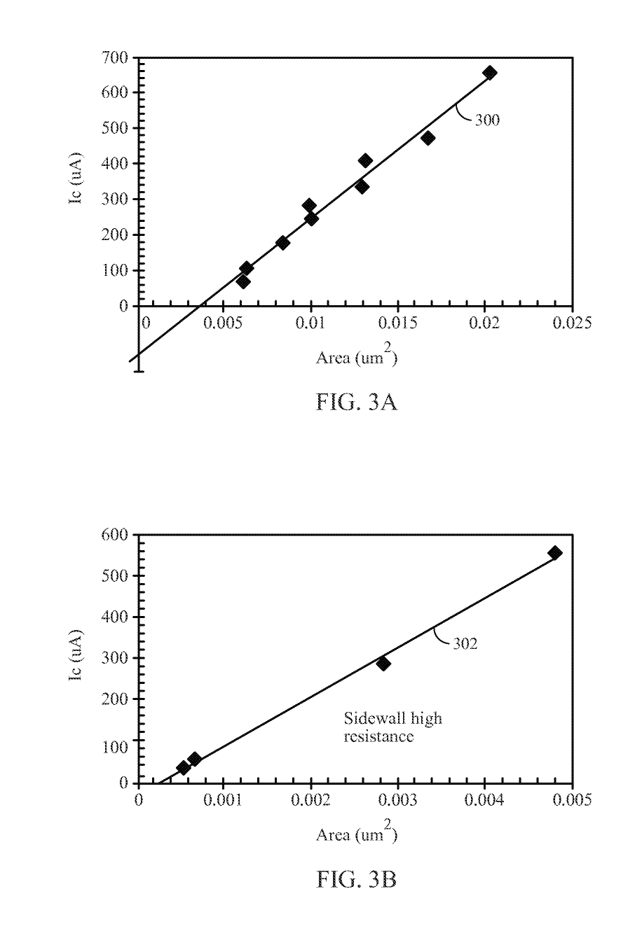

FIG. 1 illustrates a relationship between the switching current of MTJ element and the areas of those MTJ elements. As will be appreciated from the trend line 100 in FIG. 1, the relationship between MTJ switching current and MTJ area is such that, as the size of an MTJ element approaches zero, or comes within a predetermined distance of zero, the switching current for that MTJ element also approaches zero. In other words, the trend line 100 relating MTJ element switching current to MTJ element size intersects the origin of the graph. FIG. 1 illustrates a trend line for a hypothetical MTJ element that has no damage to its sidewall, a structure that is difficult or impossible to obtain with current manufacturing practices. Typically, at least some sidewall damage occurs during the MTJ manufacturing process, and trend lines for typical MTJ elements do not intersect the origin of an area vs. switching current graph. Instead, the trend line showing the relationship between MTJ element switching current and the area of the MTJ element intersects the Y-axis of the graph, this intersection representing a theoretical MTJ area of zero, at a positive or negative location. FIG. 2 shows a first trend line 200 intersecting the Y-axis at a first positive location and a second trend line 202 intersecting a Y-axis at a second positive location. FIG. 3A illustrates a first trend line 300 intersecting a Y-axis at a first negative location, and FIG. 3B illustrates a second trend line 302 intersecting the Y-axis at a second negative location. The trend lines 200, 202 of FIG. 2 could alternately be described as intersecting the X-axis at a negative location (negative X-intercept), and the trend lines 300 and 302 of FIGS. 3A and 3B could be described as intersecting the X-axis at positive locations (positive X-intercept), but because the following discussion concerns primarily an electrical characteristic of the MTJ element as the size of the MTJ element approaches zero, it is the zero size of the MTJ element and the Y-intercept of the graph that will be discussed herein. Various numbers of measurements are shown in these graphs, and it is generally desirable to use at least three measurements to determine a trend line.

The present inventors have determined that the Y-intercept of a trend line representing a relationship between an MTJ element electrical characteristic, in this case switching current, and the size of the MTJ element can be used to determine both the type of side wall damage and the amount of side wall damage, subject to certain constraints, discussed herein. When the Y-intercept of the trend line is positive, it indicates that current would, hypothetically, continue to flow when the size of the MTJ element becomes zero. This may be interpreted to indicate the existence of a damaged outer portion of the MTJ element that presents a low resistance or a high leakage path in the MTJ element. A negative Y-intercept of the trend line, on the other hand, suggests that current flow through the MTJ element would become zero before the size of the MTJ element becomes zero. This may be interpreted to indicate that a damaged portion of the MTJ element offers high resistance and thus a low leakage path. Different methods, discussed below, are used to determine a degree of side wall damage depending on whether the Y-intercept of the trend line is positive or negative.

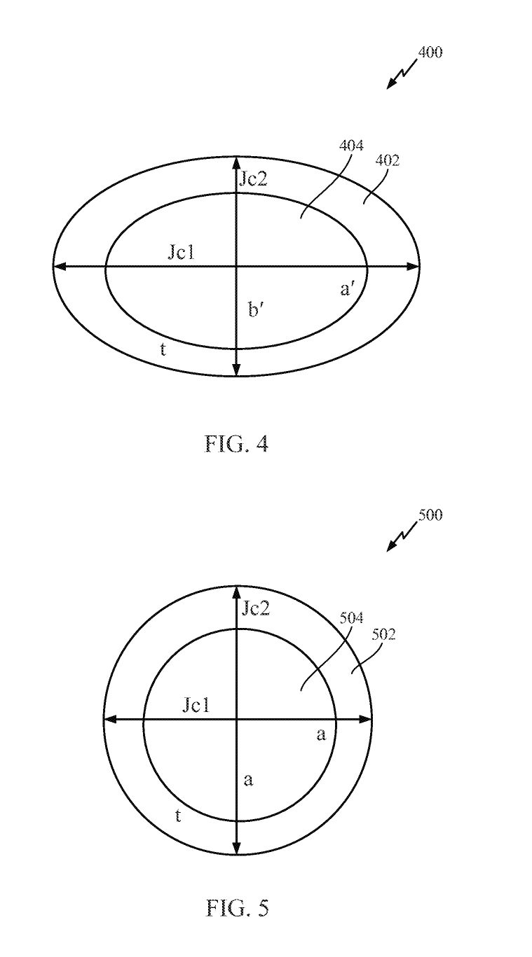

Many MTJ elements have a generally oval shape when viewed from above. FIG. 4 schematically illustrates an MTJ element 400 having a damaged outer region 402 having a thickness “t,” an undamaged inner region 404, and a major axis a′ and a minor axis b′. As an initial part of determining sidewall damage, it may be useful to determine the dimensions of an equivalent circular MTJ element 500 that has the same area as the elliptical MTJ element 400. FIG. 5 illustrates an example of such an equivalent circular MTJ element 500 having a damaged outer region 502 having a thickness “t” and an undamaged inner region 504, the MTJ element 500 having a diameter a. The area of the elliptical MTJ element 400 can be expressed as one fourth π times the major axis a′ times the minor axis b′ of the ellipse or:

$$A = \frac{π}{4} {a}^{′} {b}^{′} .$$

In the special case of an ellipse with equal major and minor axes a, i.e., a circle, the area can be expressed as

$$\frac{π}{4} {a}^{2} .$$

Setting these values equal to one another and solving for a in terms of a′ and b′ provides:

$$A = \frac{π}{4} {a}^{′} {b}^{′} = \frac{π}{4} {a}^{2}$$

and therefore a=\sqrt{a′b′}.

The value “a” is thus used hereafter to indicate the diameter of a hypothetical MTJ element 500 that has an area equal to the area of an actual elliptical MTJ element 400 the sidewall damage of which is being evaluated.

Knowing the switching current of the MTJ element 400 and the diameter a of an equivalent circular MTJ element 500, one can determine a relationship between the diameter and the current densities of the damaged outer region 402 and undamaged inner region 404 of the MTJ element 400 and the thickness t of the damaged outer region 402 of the MTJ element 400. Variables that include a subscript of “1” in the equations below relate to the undamaged inner region 504 of the MTJ element 500, and variables that have a subscript of “2” refer to the damaged outer region 502 of the MTJ element 500. For these discussions, the diameter a of the MTJ element 500 is assumed to be much greater than the thickness t of the damaged outer region 502. The following discussion first describes determining these values when the Y intercept of the trend line is found to be negative as illustrated in FIG. 3.

The switching current I_{sw} of the MTJ element 400 is equal to the sum of the switching currents of the damaged outer region 402 and the undamaged inner region 404 of the MTJ element 400, which can be expressed as:

I_{sw}=I_{c1}+I_{c2},

and this can also be expressed in terms of current densities J and the areas of the damaged outer region 402 and the undamaged inner region 404 of the MTJ element 404 as follows:

I_{sw}=J_{c1}·A₁+J_{c2}·A₂.

Because

$$A = \frac{π}{4} {a}^{2} ,$$

the area A₁ of the undamaged inner region 404 of the MTJ element 400 can be expressed as:

$${A}_{1} = \frac{π}{4} {( a - 2 t )}^{2}$$

and the area of the damaged outer region 402 of the MTJ element 400 can be expressed as:

$${A}_{2} = [ \frac{π}{4} {a}^{2} - \frac{π}{4} {( a - 2 t )}^{2} ] .$$

The switching current I_{sw} can thus be expressed as:

$${I}_{sw} = \frac{π}{4} {( a - 2 t )}^{2} \cdot {J}_{c 1} + [ \frac{π}{4} {a}^{2} - \frac{π}{4} {( a - 2 t )}^{2} ] \cdot {J}_{c 2}$$

which simplifies to:

$${I}_{s w} = [ \frac{π}{4} {a}^{2} - π a t + π {t}^{2} ] \cdot {J}_{c 1} + [ π at - π {t}^{2} ] \cdot {J}_{c 2}$$

which can also be expressed as:

$${I}_{sw} = \frac{π}{4} {J}_{c 1} \cdot {a}^{2} - π t ( {J}_{c 1} - {J}_{c 2} ) \cdot a + π {t}^{2} ( {J}_{c 1} - {J}_{c 2} ) .$$

From this equation, the following algebraic manipulations allow one to arrive at an expression for the diameter of the equivalent circular MTJ element 500:

$$\frac{π}{4} {J}_{c 1} \cdot {a}^{2} - π t ( {J}_{c 1} - {J}_{c 2} ) \cdot a + π {t}^{2} ( {J}_{c 1} - {J}_{c 2} ) - {I}_{sw} = 0$$

Solving the quadratic equation of variable a provides:

$$a = \frac{π t ( {J}_{c 1} - {J}_{c 2} ) \pm \sqrt{\begin{matrix}{( π t ( {J}_{c 1} - {J}_{c 2} ) )}^{2} - π {J}_{c 1} \cdot \\ ( π {t}^{2} ( {J}_{c 1} - {J}_{c 2} ) - {I}_{sw} )\end{matrix}}}{\frac{π}{2} {J}_{c 1}} .$$

To simplify the solution for further manipulations, we can assign the following values to new variables m, n and k:

$$m = 2 ( 1 - \frac{{J}_{c 2}}{{J}_{c 1}} ) \cdot t , n = \frac{2}{\sqrt{π {J}_{c 1}}} , k = π {t}^{2} {J}_{c 2} ,$$

and then a diameter a of an equivalent circular MTJ element 500 can be expressed in terms of current densities and thickness t of the damaged outer region 502 of the MTJ element 500 and its area as follows:

$$a = \frac{\begin{matrix}π t ( {J}_{c 1} - {J}_{c 2} ) \pm \\ \sqrt{π {J}_{c 1} [ {I}_{sw} - π {t}^{2} {J}_{c 2} \cdot ( 1 - \frac{{J}_{c 2}}{{J}_{c 1}} ) ]}\end{matrix}}{\frac{π}{2} {J}_{c 1}} = m \pm n \sqrt{{I}_{sw} - k ( 1 - \frac{{J}_{c 2}}{{J}_{c 1}} )}$$

Until this point, the solutions to various equations have not been approximated. In reality, only one solution is correct and another solution is not true due to a negative value. The following analysis considers several extreme boundary conditions to simplify the solutions in a more meaningful manner.

If the damaged outer region 502 of the MTJ element 500 exhibits a high resistance, the current density of the undamaged inner region 504 of the MTJ element 500 will be much greater than the current density of the damaged outer region 502, and the following approximations will hold:

$$a \approx m \pm n \sqrt{{I}_{sw} - k} \approx m \pm n \sqrt{{I}_{sw} ( 1 - \frac{k}{{I}_{sw}} )} \approx m \pm n \sqrt{{I}_{sw} ( 1 - \frac{π {t}^{2} {J}_{c 2}}{{I}_{sw}} )} .$$

This can also be expressed as:

$$a \approx m \pm n \sqrt{{I}_{sw} ( 1 - {( \frac{2 t}{a} )}^{2} ( \frac{{J}_{c 2}}{{J}_{c 1}} ) )} \\ where \\ ( {J}_{c 1}^{′} = \frac{{I}_{s w}}{A} = \frac{4 {I}_{sw}}{π {a}^{2}} < {J}_{c 1} = \frac{{I}_{c 1}}{{A}_{1}} ) . \qquad ( Equation 1 )$$

Then, if

$$\frac{k}{{I}_{sw}} = {( \frac{2 t}{a} )}^{2} ( \frac{{J}_{c 2}}{{J}_{c 1}^{′}} ) << 1 , \qquad$$

the solution can further be simplified under this boundary condition.

This boundary condition implies that

$$( \frac{a}{2 t} ) >> \sqrt{\frac{{J}_{c 2}}{{J}_{c 1}^{′}}}$$

and that the ratio of the size of the MTJ element 500 to the size of the damaged outer area 502 is much larger than square root of ratio of current densities of the damaged outer region 502 to total MTJ area. The plus sign in Equation 1 is selected for a meaningful solution and

$$a \approx m + n \sqrt{{I}_{s w} ( 1 - {( \frac{2 t}{a} )}^{2} ( \frac{{J}_{c 2}}{{J}_{c 1}^{′}} ) )} \approx m + n \sqrt{{I}_{s w}} ( 1 - \frac{1}{2} {( \frac{2 t}{a} )}^{2} ( \frac{{J}_{c 2}}{{J}_{c 1}^{′}} ) )$$

$$and$$

$$a \approx m + n \sqrt{{I}_{sw}} [ 1 - \frac{1}{2} \cdot \frac{π {t}^{2} {J}_{c 2}}{{I}_{sw}} ] \approx m + n \sqrt{{I}_{sw}} ( 1 - \frac{k}{2 {I}_{sw}} ) .$$

This equation can be manipulated into the following format:

$$\frac{( a - m )}{n \sqrt{{I}_{sw}}} \approx ( 1 - \frac{k}{2 {I}_{sw}} )$$

$$( because m = 2 ( 1 - \frac{{J}_{c 2}}{{J}_{c 1}} ) t \leq 2 t << n \sqrt{{I}_{sw}} = a \sqrt{\frac{{J}_{c 1}^{′}}{{J}_{c 1} }} \leq a )$$

and then rearranged as:

$$\frac{k}{2} \cdot \frac{1}{{I}_{sw}} + \frac{( a - m )}{n} \cdot \frac{1}{\sqrt{{I}_{sw}}} - 1 \approx 0.$$

From there, one can solve quadrant equations for I_{sw} as follows:

$$\begin{matrix}\frac{1}{\sqrt{{I}_{sw}}} \approx \frac{- \frac{( a - m )}{n} \pm \sqrt{\frac{{( a - m )}^{2}}{{n}^{2}} + 2 k}}{k} \\ \approx - \frac{( a - m )}{nk} \pm \sqrt{\frac{{( a - m )}^{2}}{{( nk )}^{2}} + \frac{2}{k}}\end{matrix}$$

and reformat the solutions and choose the positive, “+” sign real solution:

$$\frac{1}{\sqrt{{I}_{sw}}} \approx - \frac{( a - m )}{nk} [ 1 - \sqrt{1 + \frac{2}{k} {( \frac{nk}{a - m} )}^{2}} ] .$$

Selecting the positive root, and assuming that

$$\frac{a}{2 t} >> 1 ,$$

or a >>2t, then

$$\begin{matrix}\frac{2}{k} {( \frac{nk}{a - m} )}^{2} \approx \frac{8 {t}^{2} ( \frac{{J}_{c 2}}{{J}_{c 1}} )}{{( a - 2 ( 1 - \frac{{J}_{c 2}}{{J}_{c 1}} ) t )}^{2}} \\ \approx 2 \frac{{( \frac{2 t}{a} )}^{2} \cdot ( \frac{{J}_{c 2}}{{J}_{c 1}} )}{{( 1 - \frac{2 t}{a} )}^{2}} \\ \approx \frac{2 ( \frac{{J}_{c 2}}{{J}_{c 1}} )}{{( \frac{a}{2 t} - 1 )}^{2}} << 1.\end{matrix}$$

$$Next , \\ \frac{1}{\sqrt{{I}_{sw}}} \approx \frac{( a - m )}{nk} [ 1 - ( 1 + \frac{1}{k} {( \frac{nk}{a - m} )}^{2} ) ] \approx + ( \frac{n}{a - m} ) .$$

Furthermore, switching current correlates to MTJ size as:

$$\sqrt{{I}_{sw}} \approx \frac{a - m}{n} \approx \frac{1}{n} a - \frac{m}{n}$$

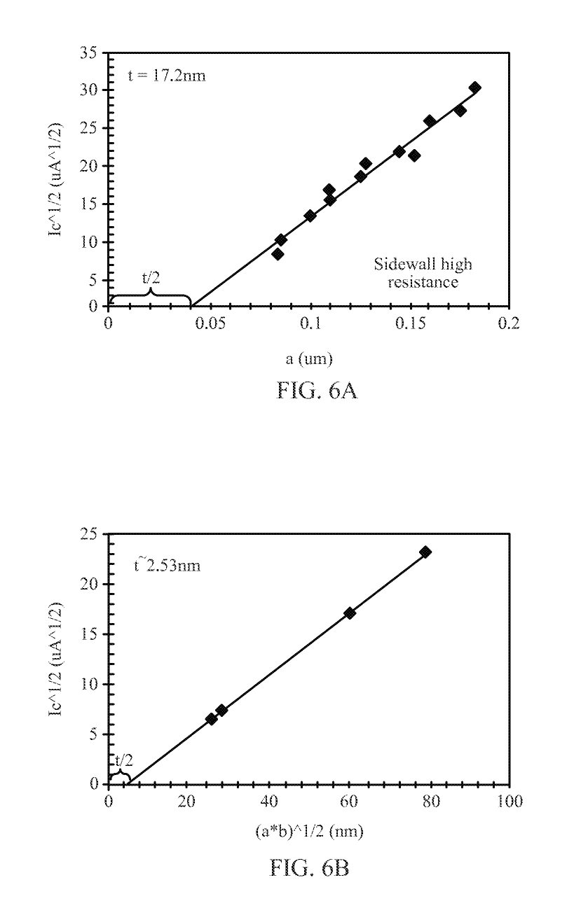

and, as shown in FIGS. 6A and 6B, one can replot \sqrt{I_{sw}} vs. a curve from a linear relation which indicates that

$$n = \frac{1}{slope} > 0 , m = - \frac{intercept}{slope} > 0$$

from which it can be seen that:

$${J}_{c 1} = \frac{4}{π {n}^{2}} and$$

$$t = \frac{m}{2 ( 1 - \frac{{J}_{c 2}}{{J}_{c 1}} )} \geq \frac{m}{2} and$$

$${J}_{c 2} \approx \frac{{I}_{sw} - \frac{π}{4} {( a - 2 t )}^{2} {J}_{c 1}}{π t ( a - t )} .$$

By measuring a′ and b′ in the MTJ element 400 and calculating a in the MTJ element 500, from FIGS. 6a and 6b, a was calculated to be 85 nm and 28 nm, and t was determined to be 17.2 nm and 2.53 nm. The ratio a/2t was thus determined to be 2.47 and 5.52 which is greater or much great than 1 and satisfies a requirement for relying upon this equation. These calculations provide suitable estimates from J_{c1}, t and J_{c2} when the Y-intercepts of the trend lines 300, 302 of the MTJ elements are negative as illustrated in FIGS. 3A and 3B.

Thus, the Y-intercept of the trend lines 300, 302 indicate the type of sidewall damage that is present (high resistance/low leakage path damage) and the magnitude of the value of t determined from the above equations indicates the degree of damage. Using these values, one can adjust at least one settable process parameter or operating parameter of a manufacturing apparatus for producing MTJ elements. The at least one settable process parameter is optimized in a first direction, increased, for example, when the Y-intercept of the trend line is negative, and optimized in a second direction, decreased, for example, when the Y-intercept of the trend line is positive. The amount by which the parameter is optimized by process can be estimated by the magnitude of t, the degree of damage to the sidewall. By an iterative process tuning of trial and error, examining the sign of the Y-intercept and the value for t as multiple batches of MTJ elements are produced with a device having a particular MTJ size splits and process optimization, MTJ elements can be produced that have a Y intercept satisfactorily close to the origin to indicate a minimal or acceptably low amount of sidewall damage and/or a damage of the type that is more tolerable for a given MTJ application.

A different approach is used when the Y-intercept of the trend line is determined to be positive as illustrated in FIG. 2. In this case, the values of J_{c1}, t and J_{c2} are calculated in two different ways, and the values obtained from these calculations are evaluated to determine whether they meet certain criteria. Only one set of values satisfies the criteria, these are the values that are used.

The first approach to determining J_{c1}, t and J_{c2} for a trend line having a positive Y-intercept is to recognize that

$$\begin{matrix}a = m \pm n \sqrt{{I}_{sw} - k ( 1 - \frac{{J}_{c 2}}{{J}_{c 1}} )} \\ = m \pm n \sqrt{{I}_{sw} + k \frac{{J}_{c 2}}{{J}_{c 1}} ( 1 - \frac{{J}_{c 2}}{{J}_{c 1}} )} ,\end{matrix}$$

and if the damaged outer region 502 of the MTJ element 500 has a low resistance, then the current density J_{c2} of the damaged outer region 502 is much greater than the current density J_{c1} of the undamaged inner region 504 and

$$\begin{matrix}\begin{matrix}a \approx m \pm n \sqrt{{I}_{sw} + k \frac{{J}_{c 2}}{{J}_{c 1}}} \\ \approx m \pm n \sqrt{{I}_{sw} ( 1 + \frac{k}{{I}_{sw}} \cdot \frac{{J}_{c 2}}{{J}_{c 1}} )} \\ \approx m \pm n \sqrt{{I}_{sw} ( 1 + \frac{π {t}^{2} {J}_{c 2}^{2}}{{I}_{sw} {J}_{c 1}} )} .\end{matrix} \\ Thus , \\ a \approx m \pm n \sqrt{{I}_{sw} ( 1 + {( \frac{2 t}{a} )}^{2} \frac{{J}_{c 2}^{2}}{{J}_{c 1}^{′} {J}_{c 1}} )} . \\ where \\ {J}_{c 1}^{′} = \frac{{I}_{sw}}{A} = \frac{4 {I}_{sw}}{π {a}^{2}} \leq {J}_{c 1} = \frac{{I}_{c 1}}{{A}_{1}} and if \\ \frac{k}{{I}_{sw}} \cdot \frac{{J}_{c 2}}{{J}_{c 1}} = {( \frac{2 t}{a} )}^{2} \frac{{J}_{c 2}^{2}}{{J}_{c 1}^{′} {J}_{c 1}} << 1\end{matrix} \qquad ( Equation 2 a )$$

this implies that

$$\frac{a}{2 t} >> \frac{{J}_{c 2}}{\sqrt{{J}_{c 1}^{′} {J}_{c 1}}} .$$

Thus, the ratio of the total size of the MTJ element 500 to the area of the damaged outer region 502 is much larger than the ratio of the current densities of outer to inner regions. Because m<0, the positive root is selected.

$$\begin{matrix}a \approx m + n \sqrt{{I}_{sw} ( 1 + {( \frac{2 t}{a} )}^{2} {( \frac{{J}_{c 2}}{\sqrt{{J}_{c 1}^{′} {J}_{c 1}}} )}^{2} )} \\ \approx m + n \sqrt{{I}_{sw}} ( 1 + \frac{1}{2} {( \frac{2 t}{a} )}^{2} {( \frac{{J}_{c 2}}{\sqrt{{J}_{c 1}^{′} {J}_{c 1}}} )}^{2} ) and\end{matrix}$$

$$\begin{matrix}a \approx m + n \sqrt{{I}_{sw}} [ 1 + \frac{1}{2} \cdot \frac{π {t}^{2} {J}_{c 2}^{2}}{{I}_{sw} {J}_{c 1}} ] \\ \approx m + n \sqrt{{I}_{sw}} [ 1 + \frac{k}{2 {I}_{sw}} ( \frac{{J}_{c 2}}{{J}_{c 1}} ) ] .\end{matrix}$$

The equation is reformatted in terms of 1/I_{sw}:

$$\frac{( a - m )}{n \sqrt{{I}_{sw}}} \approx + ( 1 + \frac{k}{2 {I}_{sw}} ( \frac{{J}_{c 2}}{{J}_{c 1}} ) )$$

and rearranged as the quadrant equation:

$$\frac{k}{2} ( \frac{{J}_{c 2}}{{J}_{c 1}} ) \cdot \frac{1}{{I}_{sw}} - \frac{( a - m )}{n} \cdot \frac{1}{\sqrt{{I}_{sw}}} + 1 \approx 0.$$

Solving the quadrant equation provides the solution:

$$\begin{matrix}\frac{1}{\sqrt{{I}_{sw}}} \approx \frac{\frac{( a - m )}{n} \pm \sqrt{\frac{{( a - m )}^{2}}{{n}^{2}} - 2 k ( \frac{{J}_{c 2}}{{J}_{c 1}} )}}{k ( \frac{{J}_{c 2}}{{J}_{c 1}} )} \\ \approx ( \frac{{J}_{c 1}}{{J}_{c 2}} ) [ \frac{( a - m )}{nk} \pm \sqrt{\frac{{( a - m )}^{2}}{{( nk )}^{2}} - \frac{2}{k} ( \frac{{J}_{c 2}}{{J}_{c 1}} )} ]\end{matrix}$$

which can be expressed as:

$$\frac{1}{\sqrt{{I}_{sw}}} \approx \frac{( a - m )}{nk} ( \frac{{J}_{c 1}}{{J}_{c 2}} ) [ 1 \pm \sqrt{1 - \frac{2}{k} {( \frac{nk}{a - m} )}^{2} ( \frac{{J}_{c 2}}{{J}_{c 1}} )} ] .$$

If a/2t is much greater than J_{c2}/J_{c1}, this implies that

$$a >> 2 t \frac{{J}_{c 2}}{{J}_{c 1}} >> 2 \text{t}$$

and that the size of the MTJ element 500 is much larger than the size of the damaged outer region 502. Therefore:

$$\frac{2}{k} {( \frac{nk}{a - m} )}^{2} ( \frac{{J}_{c 2}}{{J}_{c 1}} ) = \frac{8 {{t}^{2} ( \frac{{J}_{c 2}}{{J}_{c 1}} )}^{2}}{{( a - 2 ( 1 - \frac{{J}_{c 2}}{{J}_{c 1}} ) t )}^{2}} = 2 \frac{{( \frac{2 t}{a} )}^{2} \cdot {( \frac{{J}_{c 1}}{{J}_{c 1}} )}^{2}}{{( 1 + ( \frac{2 t}{a} ) ( \frac{{J}_{c 2}}{{J}_{c 1}} ) ( 1 - \frac{{J}_{c 1}}{{J}_{c 2}} ) )}^{2}} \approx \frac{2 {( \frac{{J}_{c 2}}{{J}_{c 1}} )}^{2}}{{( \frac{a}{2 t} + \frac{{J}_{c 2}}{{J}_{c 1}} )}^{2}} \approx \frac{2}{{( \frac{a}{2 t} \cdot \frac{{J}_{c 1}}{{J}_{c 2}} + 1 )}^{2}} << \\ Because$$

$$\frac{( a - m )}{nk} ( \frac{{J}_{c 1}}{{J}_{c 2}} ) = \frac{( a - 2 ( 1 - \frac{{J}_{c 2}}{{J}_{c 1}} ) t )}{\frac{2}{\sqrt{π {J}_{c 1}}} \cdot π {t}^{2} {J}_{c 2}} ( \frac{{J}_{c 1}}{{J}_{c 2}} ) = \frac{\sqrt{{J}_{c 1}}}{\sqrt{π t} {J}_{c 2}} ( \frac{a}{2 t} - ( 1 - \frac{{J}_{c 2}}{{J}_{c 1}} ) ) ( \frac{{J}_{c 1}}{{J}_{c 2}} ) = \frac{\sqrt{{J}_{c 1}}}{\sqrt{π t} {J}_{c 2}} ( \frac{a}{2 t} ( \frac{{J}_{c 1}}{{J}_{c 2}} ) + 1 - ( \frac{{J}_{c 1}}{{J}_{c 2}} ) ) \approx \frac{\sqrt{{J}_{c 1}}}{\sqrt{π t} {J}_{c 2}} ( \frac{a}{2 t} ( \frac{{J}_{c 1}}{{J}_{c 2}} ) + 1 ) \approx \frac{2}{\sqrt{π {J}_{c 1}} 2 t ( \frac{{J}_{c 2}}{{J}_{c 1}} )} ( ( \frac{a}{2 t} ) ( \frac{{J}_{c 1}}{{J}_{c 2}} ) ) \geq \frac{2}{\sqrt{π {J}_{c 1}} \cdot a} ( ( \frac{a}{2 t} ) ( \frac{{J}_{c 1}}{{J}_{c 2}} ) ) \approx \frac{1}{\sqrt{\frac{π}{4} {a}^{2} {J}_{c 1}}} ( ( \frac{a}{2 t} ) ( \frac{{J}_{c 1}}{{J}_{c 2}} ) ) \leq \frac{1}{\sqrt{{I}_{sw}}} ( ( \frac{a}{2 t} ) ( \frac{{J}_{c 1}}{{J}_{c 2}} ) ) >> \frac{1}{\sqrt{{I}_{sw}}}$$

the negative root is selected and

$$\frac{1}{\sqrt{{I}_{sw}}} \approx \frac{( a - m )}{nk} ( \frac{{J}_{c 1}}{{J}_{c 2}} ) [ 1 - ( 1 - \frac{1}{k} {( \frac{nk}{a - m} )}^{2} ( \frac{{J}_{c 2}}{{J}_{c 1}} ) ) ] \approx \frac{( a - m )}{nk} ( \frac{{J}_{c 1}}{{J}_{c 2}} ) [ \frac{1}{k} {( \frac{nk}{a - m} )}^{2} ( \frac{{J}_{c 2}}{{J}_{c 1}} ) ]$$

$$then$$

$$\frac{1}{\sqrt{{I}_{sw}}} \approx ( \frac{n}{a - m} ) ⇒ \sqrt{{I}_{sw}} \approx \frac{a - m}{n} \approx \frac{1}{n} a - \frac{m}{n}$$

$$slope = \frac{1}{n} > 0 , intercept = - \frac{m}{n} > 0 , m = - \frac{intercept}{slope} < 0$$

then J_{c1}, J_{c2}, and t can be extracted

$${J}_{c 1} = \frac{4}{π {n}^{2}}$$

$$and$$

$$t = \frac{m}{2 ( 1 - \frac{{J}_{c 2}}{{J}_{c 1}} )} \approx - \frac{m}{2} ( \frac{{J}_{c 1}}{{J}_{c 2}} ) \leq - \frac{m}{2}$$

$$and$$

$${J}_{c 2} \geq \frac{{I}_{sw} - \frac{π}{4} {( a - 2 t )}^{2} {J}_{c 1}}{π t ( a - t )} .$$

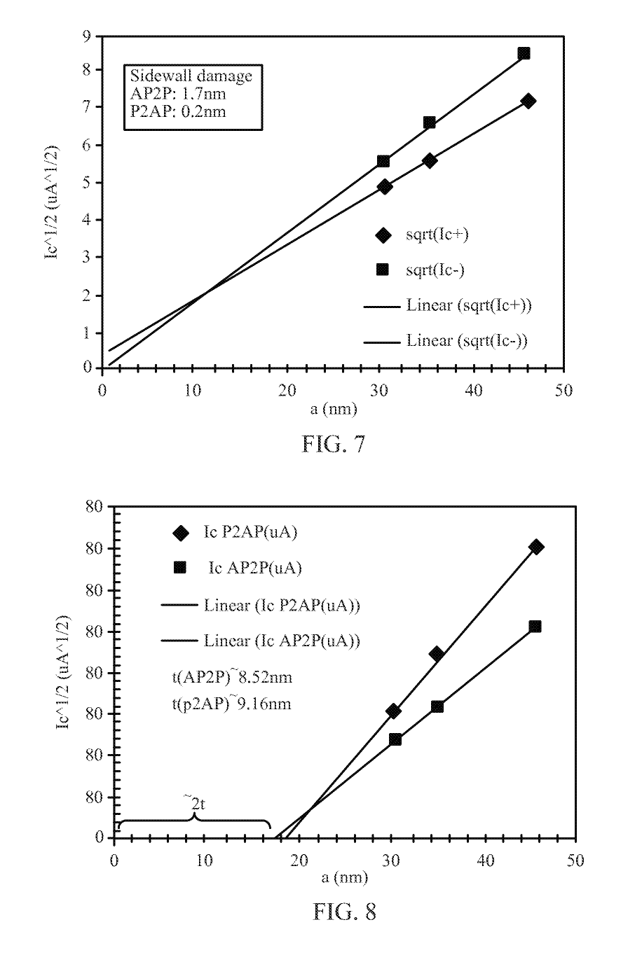

Based on actual measurements of an MTJ element 400 and calculations regarding the MTJ element 500, FIG. 7 shows that a/2t is about 10 to 80, and J_{c2}/J_{c1} equals 2, therefore a/2t is much greater than J_{c2}/J_{c1} which is greater than 1, satisfying the criteria for using this method to establish J_{c1}, t and J_{c2}.

The second set of calculations that may be used when the Y-intercept of the trend line is positive, which calculations may produce good estimates of J_{c1}, t and J_{c2} when a different simplifying method is used. Starting from

$$a = m \pm n \sqrt{{I}_{sw} - k ( 1 - \frac{{J}_{c 2}}{{J}_{c 1}} )} = m \pm n \sqrt{{I}_{sw} + k \frac{{J}_{c 2}}{{J}_{c 1}} ( 1 - \frac{{J}_{c 1}}{{J}_{c 2}} )}$$

if the damaged outer region 502 of the MTJ element 500 is a region of low resistance, the current density of the damaged outer region 502 will be much greater than the current density of the undamaged inner region 504 and the following approximations can be used:

$$a \approx m \pm n \sqrt{{I}_{sw} + k \frac{{J}_{c 2}}{{J}_{c 1}}} \approx m \pm n \sqrt{( k \frac{{J}_{c 2}}{{J}_{c 1}} ) ( 1 + \frac{{I}_{sw}}{k} \frac{{J}_{c 1}}{{J}_{c 1}} )} \approx m \pm n \sqrt{( k \frac{{J}_{c 2}}{{J}_{c 1}} )} \sqrt{1 + \frac{{I}_{s w} {J}_{c 1}}{π {t}^{2} {J}_{c 2}^{2}}}$$

and where J′_{c1} is defined as

$${J}_{c 1}^{′} = \frac{{I}_{s w}}{A} = \frac{4 {I}_{sw}}{π {a}^{2}} \leq {J}_{c 1} = \frac{{I}_{c 1}}{{A}_{1}} \\ then \\ a \approx m \pm n \sqrt{( k \frac{{J}_{c 2}}{{J}_{c 1}} )} \sqrt{1 + {( \frac{a}{2 t} )}^{2} \frac{{J}_{c 1}^{′} {J}_{c 1}}{{J}_{c 2}^{2}}} \\ If \\ \frac{{I}_{sw}}{k} \frac{{J}_{c 1}}{{J}_{c 2}} = {( \frac{a}{2 t} )}^{2} \frac{{J}_{c 1}^{′} {J}_{c 1}}{{J}_{c 2}^{2}} << 1. \qquad ( Equation 2 b )$$

this implies that

$$\frac{a}{2 t} << \frac{{J}_{c 2}}{\sqrt{{J}_{c 1}^{′} {J}_{c 1}}}$$

and the ratio of the size of the MTJ element 500 to the size of the damaged outer region 502 is much smaller than ratio of the current densities of outer to inner regions,

m=2t(1−J_{c2}/J_{c1})<0.

The positive root of Equation 2b is selected and

$$a \approx m + n \sqrt{( k \frac{{J}_{c 2}}{{J}_{c 1}} )} \sqrt{1 + {( \frac{a}{2 t} )}^{2} \frac{{J}_{c 1}^{′} {J}_{c 1}}{{J}_{c 2}^{2}}} \approx m + n \sqrt{( k \frac{{J}_{c 2}}{{J}_{c 1}} )} ( 1 + \frac{1}{2} {( \frac{a}{2 t} )}^{2} \frac{{J}_{c 1}^{′} {J}_{c 1}}{{J}_{c 2}^{2}} )$$

$$and$$

$$a \approx m + n \sqrt{( k \frac{{J}_{c 2}}{{J}_{c 1}} )} ( 1 + \frac{1}{2} \frac{{I}_{sw}}{k} \frac{{J}_{c 1}}{{J}_{c 2}} ) .$$

Thus,

$$\frac{( a - m )}{n \sqrt{k \frac{{J}_{c 2}}{{J}_{c 1}}}} \approx ( 1 + \frac{1}{2} \frac{{I}_{s w}}{k} \frac{{J}_{c 1}}{{J}_{c 2}} )$$

implies

$$\frac{( a - m )}{2 t \frac{{J}_{c 2}}{{J}_{c 1}}} \approx ( 1 + \frac{1}{2} \frac{{I}_{sw}}{k} \frac{{J}_{c 1}}{{J}_{c 2}} )$$

which implies

$$\frac{( a - m )}{2 t} \approx ( \frac{{J}_{c 2}}{{J}_{c 1}} + \frac{1}{2} \frac{{I}_{sw}}{k} ) .$$

Since

$${I}_{sw} \approx \frac{k ( a - m )}{t} - 2 k \frac{{J}_{c 2}}{{J}_{c 1}} \approx π t {J}_{c 2} ( a - m ) - 2 π {t}^{2} \frac{{J}_{c 2}^{2}}{{J}_{c 1}^{2}} \approx π t {J}_{c 2} ( a - 2 t ( 1 - \frac{{J}_{c 2}}{{J}_{c 1}} ) ) - 2 π {t}^{2} \frac{{J}_{c 2}^{2}}{{J}_{c 1}} ,$$

then

I_{sw}≈πtJ_{c2}·a−2πt²J_{c2}.

From I_{sw} vs. a linear correlation, this indicates that the slope=πtJ_{c2}>0 and the Y intercept of FIG. 8 is

−2πt²J_{c2}<0

which shows that

$$\begin{matrix}t \approx - \frac{intercept}{2 \cdot slope} \\ and & ( Equation 3 ) \\ {J}_{c 2} \approx \frac{slope}{π t} \\ and & ( Equation 4 ) \\ {J}_{c 1} \approx \frac{{I}_{sw} - {J}_{c 2} ( \frac{π}{4} {a}^{2} - \frac{π}{4} {( a - 2 t )}^{2} )}{\frac{π}{4} {( a - 2 t )}^{2}} . & ( Equation 5 )\end{matrix}$$

For the particular measurements in this case of FIG. 8, J_{c2}/J_{c1} is approximately equal to 2 which is approximately equal to a/2t, and the criterion that J_{c2}>>J_{c1}>J′_{c1} is not satisfied. The values of J_{c1}, t and J_{c2} obtained by this approach therefore may not be accurate, and the values obtained by the previous calculations should be used instead. In this case, for these conditions, Equation 2a provides a better estimate for J_{c1}, t and J_{c2}. Equations 3, 4 and 5 may provide better estimates for J_{c1}, t and J_{c2} under other conditions, and can be used when the above referenced relationships among J_{c2}, J′_{c1} and J_{c1} are satisfied. Whichever one of the values is obtained, the iterative process of adjusting at least one settable process parameter of an apparatus for producing MTJ elements is carried out as described above until the apparatus produces MTJ elements having an acceptable type and degree of sidewall damage.

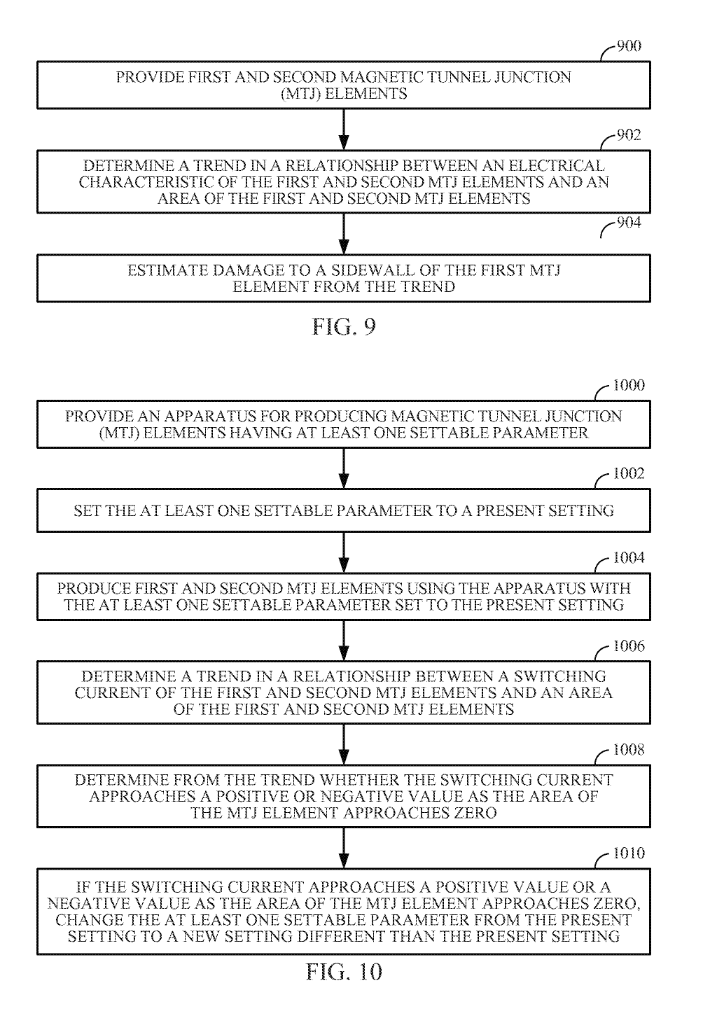

A method according to an embodiment is illustrated in FIG. 9 and includes a block 900 of providing first and second MTJ elements, a block 902 of determining a trend in a relationship between an electrical characteristic of the first and second MTJ elements and an area of the first and second MTJ elements, and a block 904 of estimating damage to a sidewall of the first MTJ element from the trend.

Another method according to an embodiment is illustrated in FIG. 10 and includes a block 1000 of providing an apparatus for producing MTJ elements having at least one settable parameter, a block 1002 of setting the at least one settable parameter to a present setting, a block 1004 of producing first and second MTJ elements using the apparatus with the at least one settable parameter set to the present setting, a block 1006 of determining a trend in a relationship between a switching current of the first and second MTJ elements and an area of the first and second MTJ elements, a block 1008 of determining from the trend whether the switching current approaches a positive or negative value as the area of the MTJ element approaches zero and a block 1010 of if the switching current approaches a positive value or a negative value as the area of the MTJ element approaches zero, changing the at least one sortable parameter from the present setting to a new setting different than the present setting.

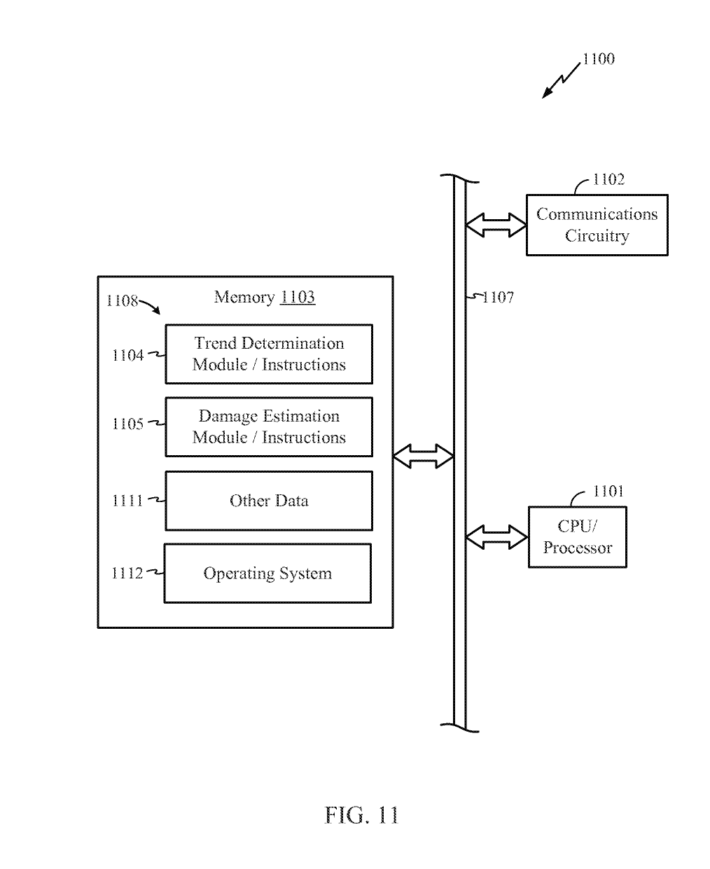

The techniques presented herein for estimating damage to MTJ elements may be implemented using any suitable means. As illustrated in FIG. 11, an apparatus 1100 may be configured to perform the operations via a set of instructions executed by one or more processors 1101.

The apparatus 1100 may be any suitable type of computer or work station and may include a central data bus 1107 linking several circuits, electronic components or boards together. The circuits/boards/electronic components include a CPU (Central Processing Unit) or a processor 1101, a communications circuit 1102 (such as a network card), and memory 1103.

The communications circuit 1102 may be configured for receiving data from and sending data to other apparatuses (e.g., other hardware units) via wired or wireless connections. The CPU/processor 1101 performs the function of data management of the data bus 1107 and further the function of general data processing, including executing the instructional contents of the memory 1103.

The memory 1103 includes a set of modules, instructions and/or data generally signified by the reference numeral 1108. In this embodiment, the modules/instructions 1108 include, among other things, a trend determination module/instructions 1104 for determining a trend in a relationship between an electrical characteristic of different MTJ elements and an area of the MTJ elements, and a damage estimation module/instructions 1105 for estimating damage to a sidewall of the MTJ elements from the trend.

The memory 1103 may include the operating system 1112 for the apparatus 1100 (e.g., Windows®, Linux®, Unix®, etc.). In addition, other data 1111 that may be used by the apparatus 1100 may also be stored in the memory 1103. The memory 1103 may be any electronic component capable of storing electronic information. The memory 1103 may be embodied as random access memory (RAM), read only memory (ROM), magnetic disk storage media, optical storage media, flash memory devices in RAM, on-board memory included with the processor, EPROM memory, EEPROM memory, an ASIC (Application Specific Integrated Circuit), registers, and so forth, including combinations thereof. It should further be noted that the inventive processes as described may also be coded as computer-readable instructions carried on any computer-readable medium known in the art.

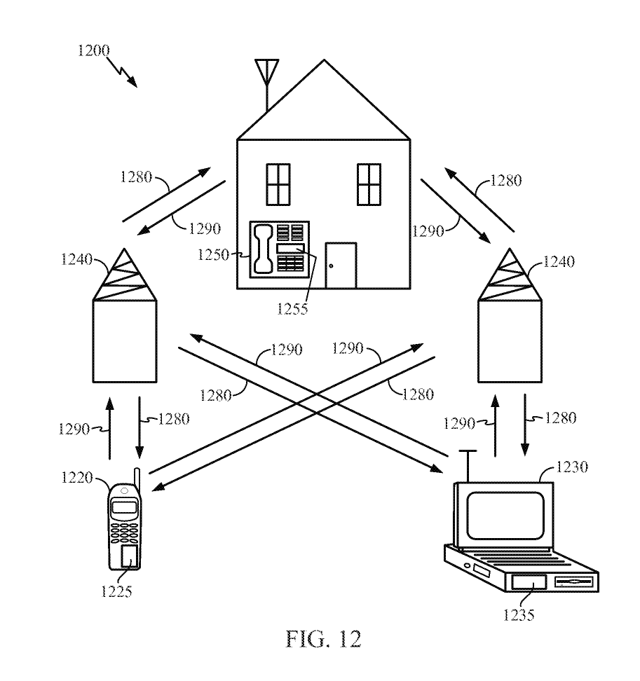

FIG. 12 illustrates an exemplary wireless communication system 1200 in which one or more embodiments produced according to the disclosure may be advantageously employed. For purposes of illustration, FIG. 12 shows three remote units 1220, 1230, and 1250 and two base stations 1240. It will be recognized that conventional wireless communication systems may have many more remote units and base stations. The remote units 1220, 1230, and 1250 include integrated circuit or other semiconductor devices 1225, 1235 and 1255, which may include embodiments produced according to the disclosure as discussed further below. FIG. 12 shows forward link signals 1280 from the base stations 1240 and the remote units 1220, 1230, and 1250 and reverse link signals 1290 from the remote units 1220, 1230, and 1250 to the base stations 1240.

In FIG. 12, the remote unit 1220 is shown as a mobile telephone, the remote unit 1230 is shown as a portable computer, and the remote unit 1250 is shown as a fixed location remote unit in a wireless local loop system. For example, the remote units may be any one or combination of a mobile phone, hand-held personal communication system (PCS) unit, portable data unit such as a personal data or digital assistant (PDA), navigation device (such as GPS enabled devices), set top box, music player, video player, entertainment unit, fixed location data unit such as meter reading equipment, or any other device that stores or retrieves data or computer instructions, or any combination thereof. Embodiments produced according to the disclosure may be suitably employed in any device having active integrated circuitry including memory and on-chip circuitry for test and characterization.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium, in the alternative, the storage medium may be integral to the processor.

Accordingly, an embodiment of the invention can include a computer readable medium embodying a method for estimating damage to the sidewall of an MTJ element or for controlling an apparatus for producing MTJ elements. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method comprising:
providing first and second magnetic tunnel junction (MTJ) elements;
determining a trend in a relationship between an electrical characteristic of the first and second MTJ elements and an area of the first and second MTJ elements; and
estimating damage to a sidewall of the first and second MTJ elements from the trend.

2. The method of claim 1, including modifying at least one operating parameter of an MTJ manufacturing apparatus based on the trend.

3. The method of claim 1, wherein determining the trend in the relationship between the electrical characteristic of the first and second MTJ elements and the area of the first and second MTJ elements comprises determining the trend in the relationship between a switching current of the first and second MTJ elements and the area of the first and second MTJ elements.

4. The method of claim 3, wherein estimating damage comprises estimating a type of damage.

5. The method of claim 3, wherein estimating damage comprises estimating a degree of damage.

6. The method of claim 3, wherein estimating damage comprises estimating a degree of damage and a type of damage.

7. The method of claim 3, wherein determining the trend in the relationship between the switching current and the area of the first and second MTJ elements comprises determining whether the switching current approaches a positive or negative value as the area of the first and second MTJ elements approaches zero.

8. The method of claim 3, including determining an X-intercept or a Y-intercept or the X-intercept and the Y-intercept of a trend line representing the trend.

9. The method of claim 8 including using a first formula to estimate damage when a sign of the Y-intercept is positive or when a sign of the X-intercept is negative and using a second formula different than the first formula to estimate damage when the sign of the Y-intercept is negative or the sign of the X-intercept is positive.

10. A method comprising:
a) providing an apparatus for producing magnetic tunnel junction (MTJ) elements having at least one settable process parameter;
b) setting the at least one settable process parameter to a present setting;
c) producing first and second MTJ elements using the apparatus with the at east one settable process parameter set to the present setting;
d) determining a trend in a relationship between a switching current of the first and second MTJ elements and an area of the first and second MTJ elements;
e) determining from the trend whether the switching current approaches a positive or negative value as the area of the MTJ element approaches zero; and
f) if the switching current approaches a positive value or a negative value as the area of the MTJ element approaches zero, changing the present selling of the at least one settable process parameter to a new setting.

11. The method of claim 10, including, after f), repeating c)-f).

12. The method of claim 10, including, after f), repeating c)-f) until the switching current approaches a value within a predetermined distance of zero when the area of the MTJ element approaches zero.

13. The method of claim 10, wherein,
if the switching current approaches a positive value as the area of the MTJ approaches zero, changing the at least one settable process parameter from the present setting to a first new setting; and
if the switching current approaches a negative value as the area of the MTJ approaches zero, changing the at least one settable process parameter from the present setting to a second new setting different than the first new setting.

14. A method comprising:
steps for providing first and second magnetic tunnel junction (MTJ) elements;
steps for determining a trend in a relationship between an electrical characteristic of the first and second MTJ elements and an area of the first and second MTJ elements; and
steps for estimating damage to a sidewall of the first and second MTJ elements from the trend.

15. The method of claim 14, including steps for modifying at least one operating parameter of an MTJ manufacturing apparatus based on the trend.

16. The method of claim 14, wherein the steps for determining a trend in a relationship between an electrical characteristic of the first and second MTJ elements and an area of the first and second MTJ elements comprise steps for determining a trend in a relationship between a switching current of the first and second MTJ elements and the area of the first and second MTJ elements.

17. A method comprising:
a) providing an apparatus for producing magnetic tunnel junction (MTJ) elements having at least one settable process parameter;
b) steps for setting the at least one settable process parameter to a present setting;
c) steps for producing first and second MTJ elements using the apparatus with the at least one settable process parameter set to the present setting;
d) steps for determining a trend in a relationship between a switching current of the first and second MTJ elements and an area of the first and second MTJ elements;
e) steps for determining from the trend whether the switching current approaches a positive or negative value as the area of the MTJ element approaches zero; and
f) steps for, if the switching current approaches a positive value or a negative value as the area of the MTJ element approaches zero, steps for changing the at least one settable process parameter from the present setting to a new setting different than the present setting.

18. The method of claim 17, including, after f), steps for repeating c)-f).

19. The method of claim 17, including, after f), steps for repeating c)-f) until the switching current approaches a value within a predetermined distance of zero when the area of the MTJ element approaches zero.

20. A non-transitory computer readable medium containing instructions, that, when executed by a computer cause the computer to receive information regarding the electrical characteristics of first and second magnetic tunnel junction (MTJ) elements and the areas of the first and second MTJ elements, determine a trend in a relationship between the electrical characteristics of the first and second MTJ elements and the areas of the first and second MTJ elements and output an estimate of damage to a sidewall of the first and second MTJ elements from the trend.

21. An apparatus for estimating damage to first and second magnetic tunnel junction (MTJ) elements, comprising:
at least one processor configured to:
determine a trend in a relationship between an electrical characteristic of the first and second MTJ elements and an area of the first and second MTJ elements, and
estimate damage to a sidewall of the first and second MTJ elements from the trend; and
memory coupled to the at least one processor and configured to store related data and/or instructions.

22. An apparatus for estimating damage to first and second magnetic tunnel junction (MTJ) elements, comprising:
means for determining a trend in a relationship between an electrical characteristic of the first and second MTJ elements and an area of the first and second MTJ elements; and
means for estimating damage to a sidewall of the first and second MTJ elements from the trend.
